(19) United States
(12) Patent Application Publication
(10) Pub. No.: US 2020/0098920 A1
(43) Pub. Date: Mar. 26, 2020

(54) TRANSISTOR GATE STRUCTURE

(71) Applicant: QUALCOMM Incorporated, San Diego, CA (US)

(72) Inventors: Fadoua CHAFIK, San Diego, CA (US); Samit SENGUPTA, San Diego, CA (US)

(21) Appl. No.: 16/140,054

(22) Filed: Sep. 24, 2018

(51) Int. Cl. H01L 29/78; H01L 29/66; H01L 29/04; H01L 21/8234

(52) U.S. Cl. CPC H01L 29/7851; H01L 29/66545; H01L 29/6656; H01L 29/0673; H01L 21/823468; H01L 21/823437; H01L 29/045

(57) ABSTRACT

A transistor gate structure includes a gate having gate sidewalls, a first side, and a second side opposite the first side. The first side may be coupled to a gate oxide layer, while the second side couples to an external device. The transistor structure also includes an inner gate spacer on the sidewalls of the gate, an outer gate spacer, and a middle gate spacer between the inner gate spacer and the outer gate spacer.

### BACKGROUND

### Field

Aspects of the present disclosure relate to semiconductor devices, and more particularly to a transistor gate structure with multiple gate spacers to mitigate gate-to-drain bridging, gate-to-source bridging, or other electrical impairments caused by gate-structure related defects.

### Background

As integrated circuit (IC) technology advances, device (e.g., semiconductor device) geometries are reduced. Reducing the geometry and “pitch” (spacing) between devices may cause devices to interfere with each other and affect proper operation.

These devices may include different types of transistors. For example, the devices may include planar transistors or fin-based transistors. Fin-based transistors are three-dimensional structures on the surface of a semiconductor substrate. A fin-based transistor, which may be a fin-based metal-oxide-semiconductor field-effect transistor (MOSFET), may be referred to as a FinFET. A nanowire or a nanosheet field-effect transistor (FET) is also a three-dimensional structure on the surface of a semiconductor substrate. A nanowire or a nanosheet FET includes doped portions of the nanowire that contact a channel region and serve as the source and drain regions of the device. A nanowire FET is also an example of a MOSFET device.

Performance of the devices (e.g., MOSFET devices) can be affected by numerous factors including channel length, spacing between gate and source/drain contacts, strain, and external resistance. Additionally, the devices may be subject to gate-to-drain bridging or gate-to-source bridging.

### SUMMARY

A transistor gate structure includes a gate having gate sidewalls, a first side and a second side opposite the first side. The transistor gate structure further includes an inner gate spacer on the sidewalls of the gate, and an outer gate spacer. Furthermore, the transistor gate structure includes a middle gate spacer between the inner gate spacer and the outer gate spacer.

A method of making a transistor gate structure includes fabricating a polysilicon gate having gate sidewalls, a first side and a second side opposite the first side. The method may also include depositing a middle gate spacer on the gate sidewalls and depositing an outer gate spacer on the middle gate spacer. The method further includes removing the polysilicon gate to create a gate cavity for a conductive gate. Furthermore, the method includes depositing an inner gate spacer on sidewalls of the middle gate spacer. The middle gate spacer is between the inner gate spacer and the outer gate spacer. The inner gate spacer contacts sidewalls of the conductive gate.

A transistor gate structure includes a gate having gate sidewalls, a first side and a second side opposite the first side. The transistor gate structure further includes an outer gate spacer and a middle gate spacer. Furthermore, the transistor gate structure includes means for strengthening the outer gate spacer and the middle gate spacer. The strengthening means is on the sidewalls of the gate. The middle gate spacer is between the strengthening means and the outer gate spacer.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer.

FIG. 2 illustrates a cross-sectional view of a metal-oxide-semiconductor field-effect transistor (MOSFET) device.

FIG. 3 illustrates a fin field-effect transistor (FinFET).

FIG. 4 illustrates an integrated circuit (IC) device including multiple gate spacers to mitigate gate-to-drain bridging or gate-to-source bridging, according to aspects of the present disclosure.

FIG. 5A illustrates an integrated circuit (IC) device with an inner gate spacer of the multiple gate spacers deposited after removal of a polysilicon gate and before source/drain epitaxy pre-cleans.

FIG. 5B illustrates an integrated circuit (IC) device with an inner gate spacer of the multiple gate spacers deposited after source/drain epitaxy pre-cleans.

FIGS. 6A to 6H illustrate a fabrication process for an integrated circuit (IC) device including multiple gate spacers to mitigate gate-to-drain bridging or gate-to-source bridging, according to aspects of the present disclosure.

FIG. 7 illustrates an integrated circuit (IC) device including multiple gate spacers to mitigate gate-to-drain bridging or gate-to-source bridging, according to aspects of the present disclosure.

FIG. 8 illustrates a method for fabricating an integrated circuit (IC) device including multiple gate spacers to mitigate gate-to-drain bridging or gate-to-source bridging, according to aspects of the present disclosure.

FIG. 9 is a block diagram showing an exemplary wireless communication system in which a transistor gate structure of the disclosure may be advantageously employed.

FIG. 10 is a block diagram illustrating a design workstation used for circuit, layout, and logic design of a transistor gate structure according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Fabrication processes (e.g., complementary metal-oxide-semiconductor (CMOS) fabrication processes) are often divided into three parts: a front-end-of-line (FEOL), a middle-of-line (MOL), and a back-end-of-line (BEOL). Front-end-of-line processes include wafer preparation, isolation, well formation, gate patterning, spacers, and dopant implantation. A middle-of-line process includes gate and terminal contact formation. Back-end-of-line processes include forming interconnects and dielectric layers for coupling to the FEOL devices. The gate and terminal contact formation of the middle-of-line (MOL) process, however, is an increasingly challenging part of the fabrication flow as a result of increased gate-to-drain bridging or gate-to-source bridging.

It will be understood that the term “layer” includes film and is not to be construed as indicating a vertical or horizontal thickness unless otherwise stated. As described herein, the term “substrate” may refer to a substrate of a diced wafer or may refer to the substrate of a wafer that is not diced. Similarly, the terms “wafer” and “die” may be used interchangeably.

Fin-based devices represent a significant advance in integrated circuit (IC) technology over planar-based devices. Fin-based devices are three-dimensional (3D) structures on a surface of a semiconductor substrate. A Fin field-effect transistor (FinFET) is a fin-based metal-oxide-semiconductor field-effect transistor (MOSFET). Unfortunately, due to the 3D structure of the FinFETs (or nanowire/nanosheet FETs), and the narrow and reduced dimensions in advanced technologies, processes such as film depositions, etch and cleans weaken transistor elements (e.g., films) especially at narrow cavities. These weakened films cause gate-to-drain bridging/leakage or gate-to-source bridging. In FinFET devices and planar devices, a spacer material is provided between a gate stack (e.g., gate metal) and the source/drain trench (CA) contacts.

As technology scaling continues, associated shrinking of a gate pitch reduces the spacer area between the source/drain trench (CA) contacts and the gate stack. This dramatically increases a potential for gate-to-drain bridging or gate-to-source bridging. This bridging defect significantly affects logic and radio frequency (RF) circuit performance because spacer size shrinks with each technology generation. Because such bridging defects are marginal and can escape time-zero screening tests and ultimately cause circuit failure over time, it is especially important for automotive applications that such defects be minimized at the source (e.g., silicon chip processing stage), prior to shipping to customers.

Chip designs for automotive applications are specified to pass stringent reliability criteria to meet one defect part per million (DPPM), which specifies extensive and expensive screenings of latent defects post-fabrication (e.g., sophisticated screening at wafer probe, burn-in, and extensive automatic test equipment (ATE) testing). Such screening or controls, however, do not catch all existing latent defects. Accordingly, shipped units are exposed to potential on-field failure.

Some implementations increase gate-to-contact spacing in a native design, resize “on mask,” or implement fabrication process tuning via lithography or etch bias. Other implementations prevent gate-to-contact misalignment due to lithography depth-of-focus differences between adjacent features (e.g., local hotspots) by re-working a lithography loop or by scrapping a wafer.

To further minimize or reduce return merchandise authorizations (RMAs) to near-zero levels, process innovations are desirable to reduce the incidence of latent defects such as gate-to-contact shorts.

Aspects of the present disclosure are directed to a gate structure or transistor structure that addresses known shortcomings with current technology, such as gate-to-source or gate-to-drain bridging. The transistor structure includes a gate having gate sidewalls, a first side, and a second side opposite the first side. The first side may be coupled to a gate oxide layer, while the second side may be configured to couple to an external device. The transistor structure also includes an inner gate spacer on the sidewalls of the gate, an outer gate spacer, and a middle gate spacer between the inner gate spacer and the outer gate spacer. A material (e.g., nitride, a fluoride, a carbide or a boride) of the inner gate spacer is different from a material (e.g., oxide) of the middle gate spacer. The inner gate spacer is deposited after polysilicon removal and before depositing a conductive gate material (e.g., gate high-K/metal) in a gate cavity, as well as after the middle and outer gate spacers are deposited.

The transistor may include a FIN field-effect transistor. According to additional aspects of the present disclosure, the transistor may be a planar transistor structure or a gate all around (GAA) transistor.

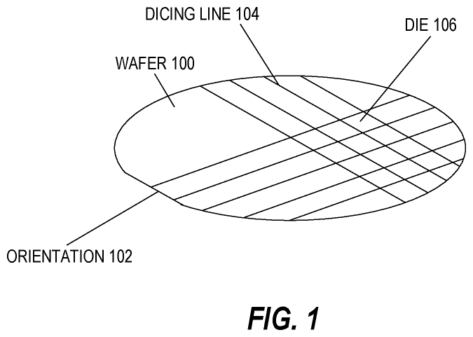

FIG. 1 illustrates a perspective view of a semiconductor wafer. A wafer 100 may be a semiconductor wafer, or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants, and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, different types of electronic devices may be formed in or on the wafer 100.

The wafer 100 has an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller indices for the planes of the crystal lattice in the wafer 100.

The Miller indices form a notation system of the crystallographic planes in crystal lattices. The lattice planes may be indicated by three integers h, k, and f, which are the Miller indices for a plane (hkl) in the crystal. Each index denotes a plane orthogonal to a direction (h, k, l) in the basis of the reciprocal lattice vectors. The integers are usually written in lowest terms (e.g., their greatest common divisor should be 1). Miller index 100 represents a plane orthogonal to direction h; index 010 represents a plane orthogonal to direction k, and index 001 represents a plane orthogonal to €. For some crystals, negative numbers are used (written as a bar over the index number) and for some crystals, such as gallium nitride, more than three numbers may be employed to adequately describe the different crystallographic planes.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

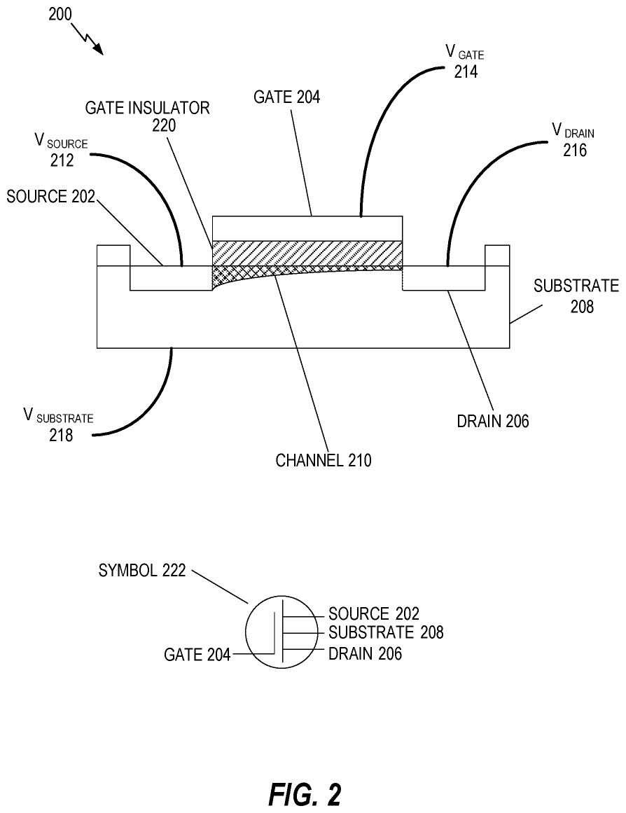

FIG. 2 illustrates a cross-sectional view of a metal-oxide-semiconductor field-effect transistor (MOSFET) device 200. The MOSFET device 200 may have four input terminals. The four inputs are a source 202, a gate 204, a drain 206, and a body. The source 202 and the drain 206 may be fabricated as the wells in a substrate 208, or may be fabricated as areas above the substrate 208, or as part of other layers on the die 106. Such other structures may be a fin or other structure that protrudes from a surface of the substrate 208. Further, the substrate 208 may be a substrate on the die 106, but the substrate 208 may also be one or more of the layers that are coupled to the substrate on the die 106.

The MOSFET device 200 is a unipolar device, as electrical current is produced by only one type of charge carrier (e.g., either electrons or holes) depending on the type of MOSFET. The MOSFET device 200 operates by controlling the amount of charge carriers in a channel 210 between the source 202 and the drain 206. A voltage Vsource 212 is applied to the source 202, a voltage Vgate 214 is applied to the gate 204, and a voltage Vdrain 216 is applied to the drain 206. A separate voltage Vsubstrate 218 may also be applied to the substrate 208, although the voltage Vsubstrate 218 may be coupled to one of the voltage Vsource 212, the voltage Vgate 214, or the voltage Vdrain 216.

To control the charge carriers in the channel 210, the voltage Vgate 214 creates an electric field in the channel 210 when the gate 204 accumulates charges. The opposite charge to that accumulating on the gate 204 begins to accumulate in the channel 210. A gate insulator 220 insulates the charges accumulating on the gate 204 from the source 202, the drain 206, and the channel 210. The gate 204 and the channel 210, with the gate insulator 220 in between, create a capacitor, and as the voltage Vgate 214 increases, the charge carriers on the gate 204, acting as one plate of this capacitor, begin to accumulate. This accumulation of charges on the gate 204 attracts the opposite charge carriers into the channel 210. Eventually, enough charge carriers are accumulated in the channel 210 to provide an electrically conductive path between the source 202 and the drain 206. This condition may be referred to as opening the channel of the FET.

By changing the voltage Vsource 212 and the voltage Vdrain 216, and their relationship to the voltage Vgate 214, the amount of voltage applied to the gate 204 that opens the channel 210 may vary. For example, the voltage Vsource 212 is usually of a higher potential than that of the voltage Vdrain 216. Making the voltage differential between the voltage Vsource 212 and the voltage Vdrain 216 larger will change the amount of the voltage Vgate 214 used to open the channel 210. Further, a larger voltage differential will change the amount of electromotive force moving charge carriers through the channel 210, creating a larger current through the channel 210.

The gate insulator 220 material may be silicon oxide, or may be a dielectric or other material with a different dielectric constant (k) than silicon oxide. Further, the gate insulator 220 may be a combination of materials or different layers of materials. For example, the gate insulator 220 may be Aluminum Oxide, Hafnium Oxide, Hafnium Oxide Nitride, Zirconium Oxide, or laminates and/or alloys of these materials. Other materials for the gate insulator 220 may be used without departing from the scope of the present disclosure.

By changing the material for the gate insulator 220, and the thickness of the gate insulator 220 (e.g., the distance between the gate 204 and the channel 210), the amount of charge on the gate 204 to open the channel 210 may vary. A symbol 222 showing the terminals of the MOSFET device 200 is also illustrated. For N-channel MOSFETs (using electrons as charge carriers in the channel 210), an arrow is applied to the substrate 208 terminal in the symbol 222 pointing away from the gate 204 terminal. For p-type MOSFETs (using holes as charge carriers in the channel 210), an arrow is applied to the substrate 208 terminal in the symbol 222 pointing toward the gate 204 terminal.

The gate 204 may also be made of different materials. In some designs, the gate 204 is made from polycrystalline silicon, also referred to as polysilicon or poly, which is a conductive form of silicon. Although referred to as “poly” or “polysilicon”, metals, alloys, or other electrically conductive materials are contemplated as appropriate materials for the gate 204 as described in the present disclosure.

In some MOSFET designs, a high-k value material may be desired in the gate insulator 220, and in such designs, other conductive materials may be employed. For example, and not by way of limitation, a “high-k metal gate” design may employ a metal, such as copper, for the gate 204 terminal. Although referred to as “metal,” polycrystalline materials, alloys, or other electrically conductive materials are contemplated as appropriate materials for the gate 204 as described in the present disclosure.

To interconnect to the MOSFET device 200, or to interconnect to other devices in the die 106 (e.g., semiconductor), interconnect traces or layers are used. These interconnect traces may be in one or more of layers (e.g., 210-214), or may be in other layers of the die 106.

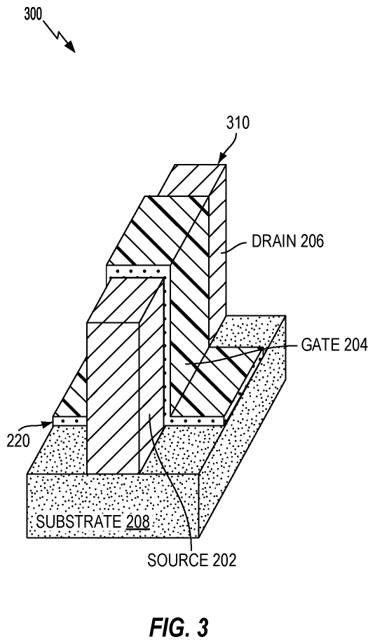

FIG. 3 illustrates a fin-structured FET (FinFET 300) that operates in a similar fashion to the MOSFET device 200 described with respect to FIG. 3. According to aspects of the present disclosure, the FinFET 300 may include multiple gate spacers. A fin 310 in a FinFET 300, however, is grown or otherwise coupled to the substrate 208. The substrate 208 may be a semiconductor substrate or other like supporting layer, for example, comprised of an oxide layer, a nitride layer, a metal oxide layer, or a silicon layer. The fin 310 includes the source 202 and the drain 206. The gate 204 is disposed on the fin 310 and on the substrate 208 through the gate insulator 220. A FinFET transistor is a 3D fin-based metal-oxide-semiconductor field-effect transistor (MOSFET). As a result, the physical size of the FinFET 300 may be smaller than the MOSFET device 200 structure shown in FIG. 2. This reduction in physical size allows for more devices per unit area on the die 106.

Applicants note that the illustrations in the FIGURES are directed to a process of adding an inner gate spacer for a transistor, and not fully inclusive of all aspects of a cross-section of a transistor. For example, in some of the drawings, the source/drain regions and contacts are not shown. The transistor dimensions are not to scale. For example, gate to gate spacing, gate length of thin gate oxide and thick gate oxide devices, spacing between thin gate oxide and thick gate oxide devices, etc., are not to scale.

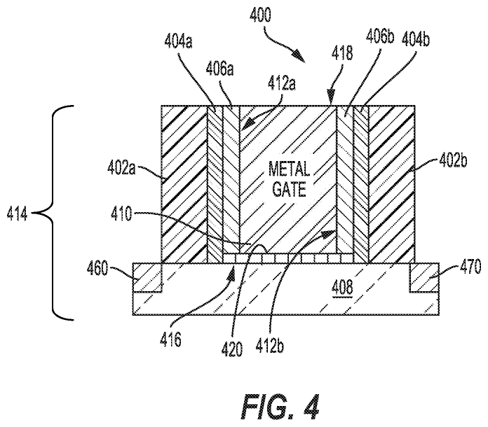

FIG. 4 illustrates an integrated circuit (IC) device 400 including multiple gate spacers to mitigate gate-to-drain bridging or gate-to-source bridging, according to aspects of the present disclosure. The IC device 400 includes multiple gate spacers formed on sidewalls of a gate 410. The IC device 400 may include a gate structure or transistor structure 414 that addresses known shortcomings with current technology, such as gate-to-source or gate-to-drain bridging. The IC device 400 includes a gate (e.g., the conductive gate 410) having gate sidewalls (e.g., a first sidewall 412a and a second sidewall 412b). The transistor structure 414 includes a first side 416 and a second side 418 opposite the first side 416. The first side 416 may be coupled to a gate insulator 420 while the second side 418 may be configured to couple to an external device. The IC device 400 also includes a substrate 408. The substrate 408 includes a source region 460 and a drain region 470.

The transistor structure 414 also includes inner gate spacers (e.g., a first inner gate spacer 406a and a second inner gate spacer 406b) on the sidewalls (e.g., a first sidewall 412a and a second sidewall 412b) of the conductive gate 410, outer gate spacers (e.g., a first outer gate spacer 402a and a second outer gate spacer 402b) and middle gate spacers (e.g., a first middle gate spacer 404a and a second middle gate spacer 404b) between the inner gate spacers and the outer gate spacers. A width of the first outer gate spacer 402a and the second outer gate spacer 402b is approximately ten (10)-twenty (20) nanometers (nm) depending on the technology. A width of the first middle gate spacer 404a and the second middle gate spacer 404b is approximately two (2)-four (4) nm depending on the technology. A width of the first inner gate spacer 406a and the second inner gate spacer 406b is also approximately two (2)-four (4) nm depending on the technology. The first middle gate spacer 404a is between the first inner gate spacer 406a and the first outer gate spacer 402a. The second middle gate spacer 404b is between the second inner gate spacer 406b and the second outer gate spacer 402b.

The transistor structure 414 may be a FIN field-effect transistor structure, a planar transistor structure, a nanowire transistor structure or a nanosheet transistor structure. A material (e.g., a nitride, a fluoride, a carbide, an oxide or a boride) of the first inner gate spacer 406a and/or the second inner gate spacer 406b is different from a material (e.g., oxide) of the first middle gate spacer 404a and/or the second middle gate spacer 404b.

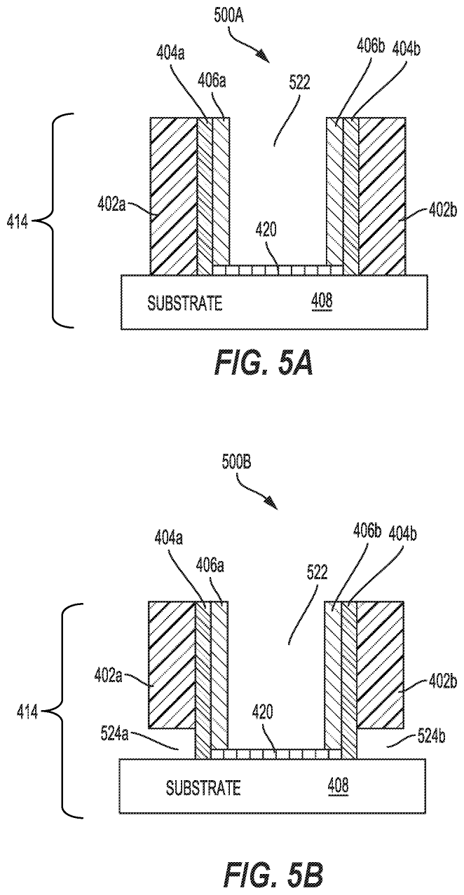

FIG. 5A illustrates an integrated circuit (IC) device 500A with an inner gate spacer of the multiple gate spacers deposited after removal of a polysilicon gate and before source/drain epitaxy pre-cleans. For illustrative purposes, some of the labelling and numbering of the devices and features of FIG. 5A are similar to those of FIG. 4.

In one aspect of the disclosure, the first inner gate spacer 406a and the second inner gate spacer 406b are deposited or formed in the gate cavity 522 after the removal of a dummy gate (e.g., polysilicon gate) and before a permanent conductive gate material is deposited in the gate cavity 522. For example, the conductive gate material to be deposited in the gate cavity 522 may be a high-K material and/or a metal. The first inner gate spacer 406a and the second inner gate spacer 406b are also deposited after the first middle gate spacer 404a and the second middle gate spacer 404b and after the first outer gate spacer 402a and the second outer gate spacer 402b.

According to aspects of the present disclosure, the first inner gate spacer 406a and/or the second inner gate spacer 406b may be deposited using liner/spacer deposition methods such as atomic layer deposition (ALD), plasma enhanced chemical vapor deposition (PECVD), low pressure chemical vapor deposition (LPCVD). Other processes may also be utilized to fabricate the first inner gate spacer 406a and/or the second inner gate spacer 406b.

FIG. 5B illustrates an integrated circuit (IC) device 500B with an inner gate spacer of the multiple gate spacers deposited after source/drain epitaxy pre-cleans. For illustrative purposes, some of the labelling and numbering of the devices and features of FIG. 5B are similar to those of FIGS. 4 and 5A.

After polysilicon gate removal and after source/drain epitaxy pre-cleans, the middle gate spacers and the outer gate spacers weaken from inside and outside a gate cavity or recess 522. The weakening of the middle gate spacers and the outer gate spacers causes a conductive gate material to leak through the gate cavity 522. This defect is especially prominent at a gate bottom (e.g., a first gate bottom region 524a and a second gate bottom region 524b). The weakening of the middle gate spacers and the outer gate spacers may be due to different cleans and their corresponding chemical reactions between different cleaning materials. The first inner gate spacer 406a and the second inner gate spacer 406b are included to mitigate the weakening of the middle gate spacers and the outer gate spacers.

The inner gate spacers provide additional protection from chemical attack during subsequent steps, such as “pre-clean” for high-K and metal gate deposition or source-drain epitaxy. For example, the inner gate spacers prevent erosion of sidewalls of a conductive gate that correspond to sidewalls of the spacers. The additional protection eliminates or mitigates gate material leaks, shorts, and device failures.

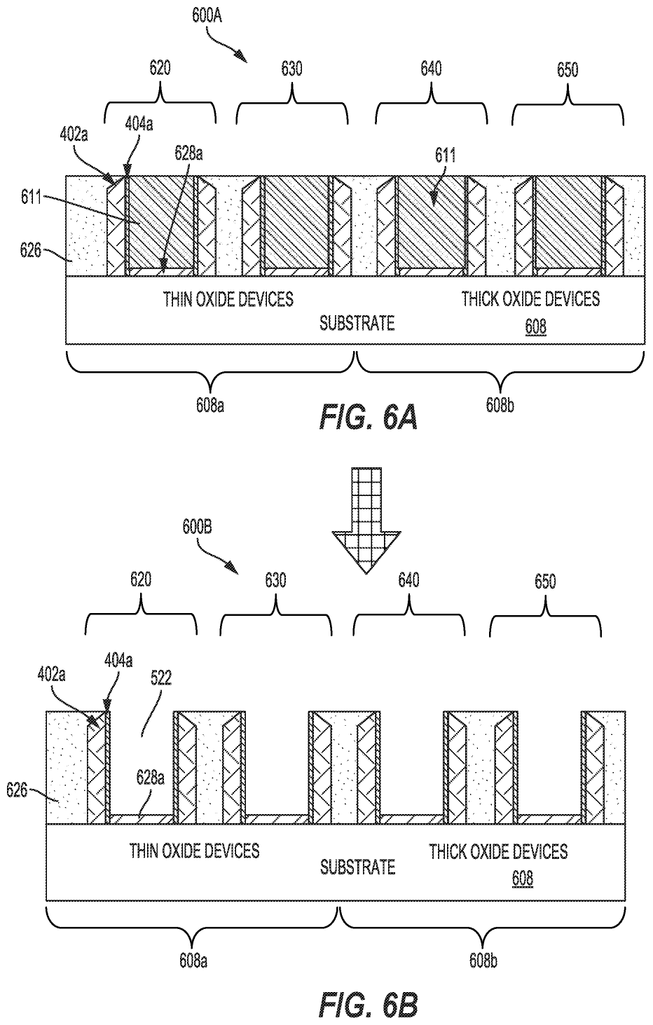

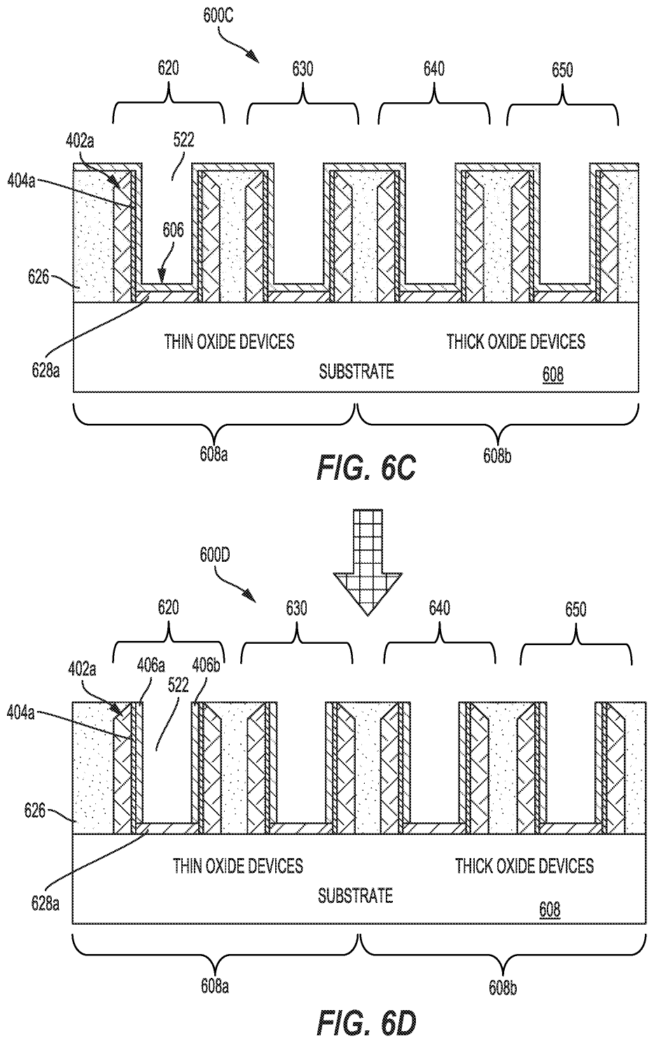

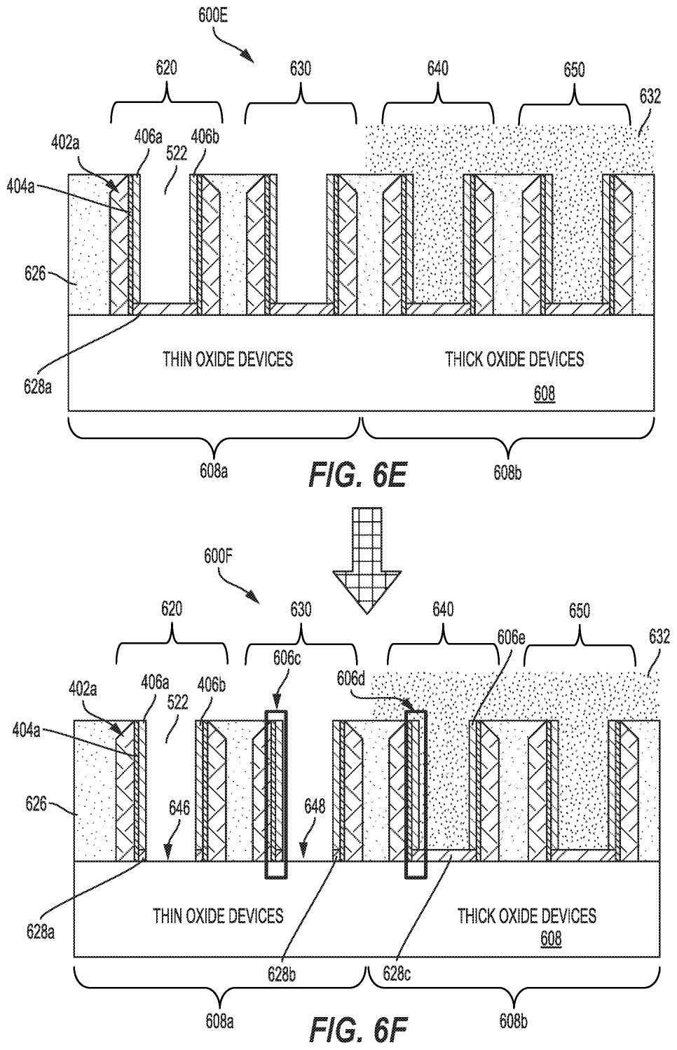

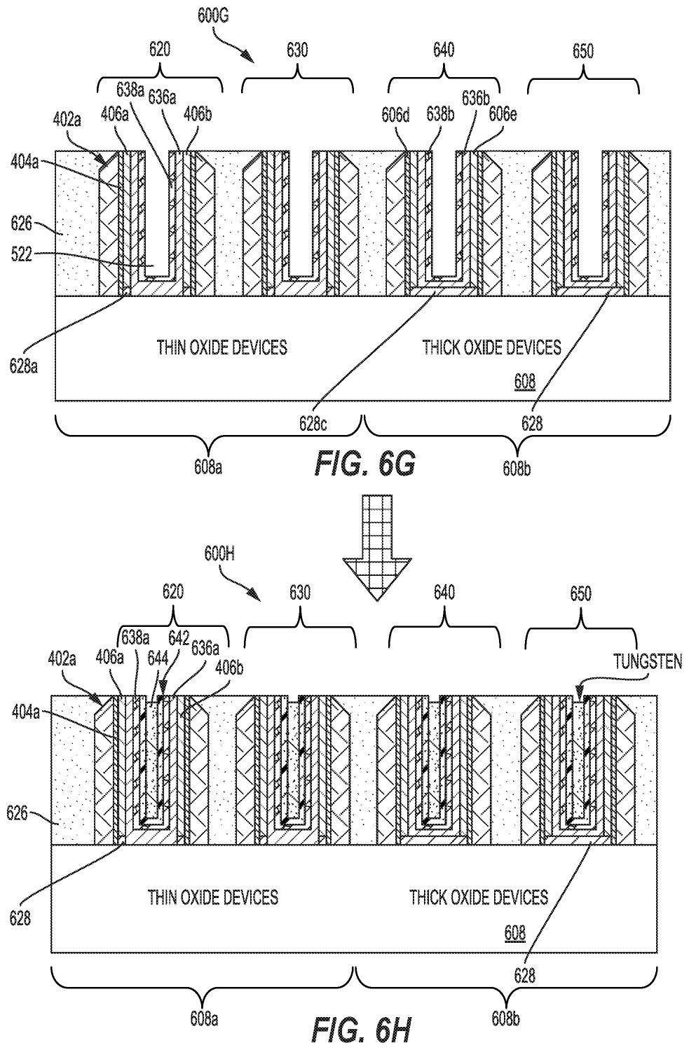

FIGS. 6A-6H illustrate a fabrication process for an integrated circuit (IC) device including multiple gate spacers to mitigate gate-to-drain bridging or gate-to-source bridging, according to aspects of the present disclosure. For illustrative purposes, some of the labelling and numbering of the devices and features of FIGS. 6A-6H are similar to those of FIGS. 4, 5A and 5B. The integrated circuit devices of FIGS. 6A-6H each include transistor structures (e.g., a first transistor structure 620, a second transistor structure 630, a third transistor structure 640, and a fourth transistor structure 650). The first transistor structure 620 and the second transistor structure 630 are thin gate oxide devices in a thin gate oxide region 608a of a substrate 608. The third transistor structure 640 and the fourth transistor structure 650 are thick gate oxide devices in a thick gate oxide region 608b of the substrate 608. Each of the transistor structures is similar except for their gate insulator (e.g., gate insulator 628a) thicknesses. For example, the gate insulators of the first transistor structure 620 and the second transistor structure 630 are thin relative to thick gate insulators of the third transistor structure 640 and the fourth transistor structure 650. Accordingly, the description is focused on one of the transistor structures that includes most of the labelling with a few mentions of features in other transistor structures to highlight differences.

Referring to FIG. 6A, a first stage of the fabrication process for the integrated circuit device with multiple gate spacers is depicted and generally designated 600A. FIG. 6A illustrates multiple transistor structures including gate oxide regions. An encapsulation material 626 partially surrounds the first transistor structure 620, the second transistor structure 630, the third transistor structure 640, and the fourth transistor structure 650. For example, the encapsulation material 626 is on sidewalls of the transistor structures and on the substrate.

The first transistor structure 620 includes the first outer gate spacer 402a and the first middle gate spacer 404a. The first middle gate spacer 404a is formed on sidewalls of a dummy gate, e.g., polysilicon gate 611 and is between the polysilicon gate 611 and the first outer gate spacer 402a. The polysilicon gate 611 is disposed on a gate insulator 628a (e.g., a gate oxide).

Referring to FIG. 6B, a second stage of the fabrication process for the integrated circuit device with multiple gate spacers is depicted and generally designated 600A. For illustrative purposes, some of the labelling and numbering of the devices and features of FIG. 6B are similar to those of FIG. 6A. FIG. 6B illustrates removal of the polysilicon gate 611 to expose a gate cavity or recess (e.g., the gate cavity 522). The polysilicon gate 611 may be removed by dry etching to form the gate cavity 522 and other standard process flows such as wet clean.

Referring to FIG. 6C, a third stage of the fabrication process for the integrated circuit device with multiple gate spacers is depicted and generally designated 600C. For illustrative purposes, some of the labelling and numbering of the devices and features of FIG. 6C are similar to those of FIGS. 6A-6B. After removal of the polysilicon gate 611 a layer of inner gate spacer 606 is deposited over the first transistor structure 620, the second transistor structure 630, the third transistor structure 640, and the fourth transistor structure 650. For example, the layer of inner gate spacer 606 is on sidewalls of the middle gate spacers, on surfaces of the gate insulators (e.g., the gate insulator 628a), and between the transistor structures.

Referring to FIG. 6D, a fourth stage of the fabrication process for the integrated circuit device with multiple gate spacers is depicted and generally designated 600D. For illustrative purposes, some of the labelling and numbering of the devices and features of FIG. 6D are similar to those of FIGS. 6A-6C. After depositing the inner gate spacer 606, reactive ion etching (RIE) is performed to remove portions of the inner gate spacer 606. Portions of the inner gate spacer 606 on the gate insulator 628a and between the transistor structures are removed to expose a surface of the gate insulator and surfaces between the transistor structures. For example, remaining portions of the inner gate spacer 606 include the first inner gate spacer 406a and the second inner gate spacer 406b of the first transistor structure 620.

Referring to FIG. 6E, a fifth stage of the fabrication process for the integrated circuit device with multiple gate spacers is depicted and generally designated 600E. For illustrative purposes, some of the labelling and numbering of the devices and features of FIG. 6E are similar to those of FIGS. 6A-6D. After removing portions of the inner gate spacer 606, a lithography process is used to block portions of the thick gate oxide devices and to open portions of the thin gate oxide devices. For example, the transistor structures corresponding to the thick gate oxide region 608b are protected with a material 632 (e.g., a photoresist or dielectric that is defined by the mask) during etching.

Referring to FIG. 6F, a sixth stage of the fabrication process for the integrated circuit device with multiple gate spacers is depicted and generally designated 600F. For illustrative purposes, some of the labelling and numbering of the devices and features of FIG. 6F are similar to those of FIGS. 6A-6E.

FIG. 6F illustrates etching (e.g., dry etching or anisotropic etching) of at least a portion of the gate insulators (e.g., the gate insulator 628a) in the transistor structures corresponding to the thin gate oxide region 608a. The gate insulators (e.g., a gate insulator 628c) of the transistor structures corresponding to the thick gate oxide region 608b are protected by the material 632. For example, the removal of at least the portion of the gate insulator 628a and a portion of a gate insulator 628b in the transistor structures corresponding to the thin gate oxide region 608a exposes at least a portion (e.g., surfaces 646 and 648) of the substrate 608 of each of the first transistor structure 620 and the second transistor structure 630. The inner gate spacers are formed in all of the transistor structures for improved gate edge protection or gate bottom protection. For example, a third inner gate spacer 606c is formed in the second transistor structure 630 and a fourth inner gate spacer 606d is formed in the third transistor structure 640. These inner gate spacers achieve robust gate-edge protection. The material 632 is stripped off before the next process step.

Referring to FIG. 6G, a seventh stage of the fabrication process for the integrated circuit device with multiple gate spacers is depicted and generally designated 600G. For illustrative purposes, some of the labelling and numbering of the devices and features of FIG. 6G are similar to those of FIGS. 6A-6F. FIG. 6G illustrates depositing of an interface layer 636a and depositing of a high-K material 638a on the interface layer 636a. For example, in the first transistor structure 620, the interface layer 636a is deposited on sidewalls of the first inner gate spacer 406a, on sidewalls of the second inner gate spacer 406b and on a surface of the substrate 608. However, in the third transistor structure 640, an interface layer 636b is deposited on sidewalls of a fourth inner gate spacer 606d, on sidewalls of a fifth inner gate spacer 606e and on a surface of the gate insulator 628c.

Referring to FIG. 6H, an eighth stage of the fabrication process for the integrated circuit device with multiple gate spacers is depicted and generally designated 600H. For illustrative purposes, some of the labelling and numbering of the devices and features of FIG. 6H are similar to those of FIGS. 6A-6G. FIG. 6H illustrates depositing of a first conductive gate material 642 and depositing of a second conductive gate material 644 on the interface layer 636a. For example, the first conductive gate material 642 is deposited on sidewalls of the high-K material 638a and on a surface of the high-K material 638a. Subsequent to the deposition of the high-K material 638a, another material (e.g., lanthanum) can be deposited to modulate an effective work-function. Alternatively, surface treatments can be applied to the high-K material 638a to modulate the effective work-function. The second conductive gate material 644 is deposited on sidewalls of the first conductive gate material 642 and on a surface of the first conductive gate material 642. In one aspect, the conductive gate materials can be tungsten (W), aluminum (Al), titanium (Ti), aluminum doped titanium carbide (TiAlC), titanium nitride (TiN), tantalum nitride (TaN), etc.

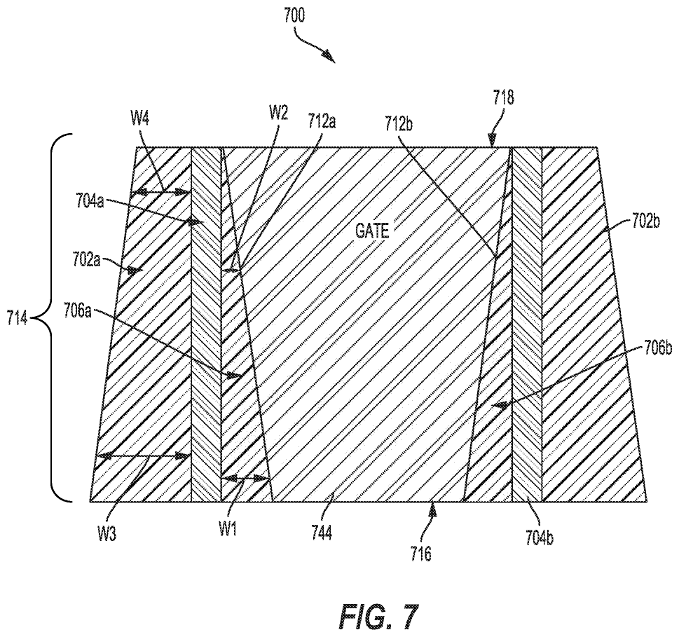

FIG. 7 illustrates an integrated circuit (IC) device 700 including multiple gate spacers to mitigate gate-to-drain bridging or gate-to-source bridging, according to aspects of the present disclosure. The integrated circuit (IC) device 700 includes multiple gate spacers formed on sidewalls of a conductive gate 744. The IC device 700 may include a gate structure or transistor structure 714 that addresses known shortcomings with current technology such as gate-to-source or gate-to-drain bridging. The conductive gate 744 includes gate sidewalls (e.g., a first sidewall 712a and a second sidewall 712b). The transistor structure 714 includes a first side 716 and a second side 718 opposite the first side 716. The first side 716 may be coupled to a substrate (e.g., the substrate 408 of FIG. 4) while the second side 718 may be configured to couple to an external device.

The transistor structure 714 also includes inner gate spacers (e.g., a first inner gate spacer 706a or a second inner gate spacer 706b) on the gate sidewalls (e.g., the first sidewall 712a and the second sidewall 712b), outer gate spacers (e.g., a first outer gate spacer 702a and a second outer gate spacer 702b) and middle gate spacers (e.g., a first middle gate spacer 704a and a second middle gate spacer 704b) between the inner gate spacers and the outer gate spacers. For example, the first middle gate spacer 704a is between the first inner gate spacer 706a and the first outer gate spacer 702a. Similarly, the second middle gate spacer 704b is between the second inner gate spacer 706b and the second outer gate spacer 702b.

The inner gate spacers may be deposited in a gate cavity such that the inner gate spacers are tapered. For example, a first width W1 of the first inner gate spacer 706a adjacent to the first side 716 is larger than a second width W2 of the first inner gate spacer 706a adjacent to the second side 718. The outer gate spacers may be deposited on the middle gate spacers such that the outer gate spacers are tapered. For example, a third width W3 of the first outer gate spacer 702a adjacent to the first side 716 is larger than a fourth width W4 of the first outer gate spacer 702a adjacent to the second side 718. A material (e.g., nitride) of the first inner gate spacer 706a and/or the second inner gate spacer 706b is different from a material (e.g., oxide) of the first middle gate spacer 704a and/or the second middle gate spacer 704b. In some aspects, a material (e.g., nitride) of the first outer gate spacer 702a and/or the second outer gate spacer 702b is different from the material (e.g., oxide) of the first middle gate spacer 704a and/or the second middle gate spacer 704b. In some configurations, nitrogen is a key element in the inner gate spacers, with carbon, boron, aluminum, silicon, and oxygen being other possible components of the inner gate spacers.

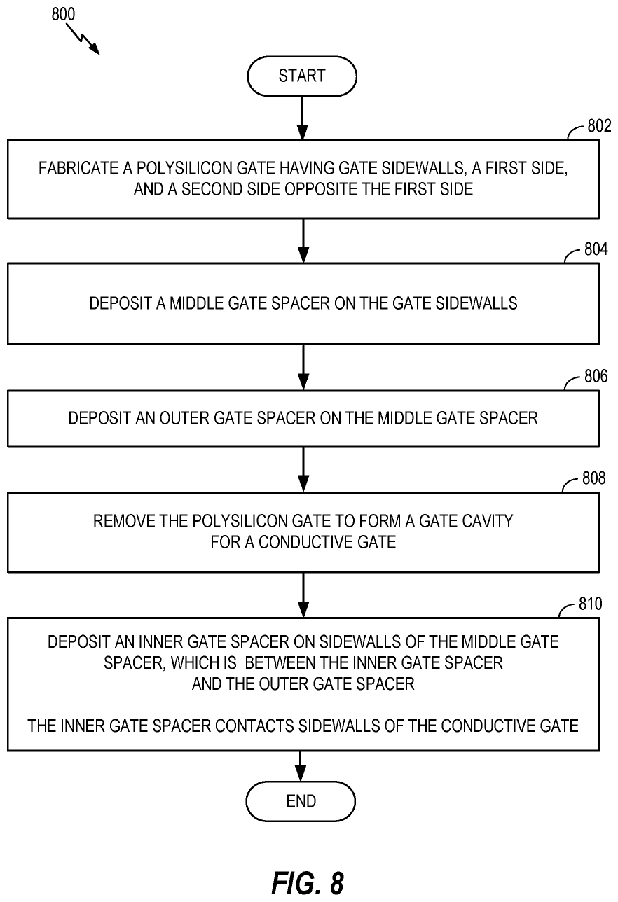

FIG. 8 illustrates a method 800 for fabricating an integrated circuit (IC) device including multiple gate spacers to mitigate gate-to-drain bridging or gate-to-source bridging, according to aspects of the present disclosure. The method 800 begins at block 802, where a polysilicon gate having gate sidewalls, a first side, and a second side opposite the first side is fabricated. At block 804, a middle gate spacer is deposited on sidewalls of the polysilicon gate. At block 806, an outer gate spacer is deposited on the middle gate spacer. At block 808, the polysilicon gate is removed to create a gate cavity for a conductive gate. At block 810, an inner gate spacer is deposited on sidewalls of the middle gate spacer. The middle gate spacer is between the inner gate spacer and the outer gate spacer. The inner gate spacer contacts sidewalls of the conductive gate

According to an aspect of the present disclosure, an integrated circuit (IC) device is described. In one configuration, the IC device includes means for strengthening the outer gate spacer and the middle gate spacer. The strengthening means may be the first inner gate spacer 406a and/or the second inner gate spacer 406b. In another aspect, the aforementioned means may be any module or any apparatus or material configured to perform the functions recited by the aforementioned means.

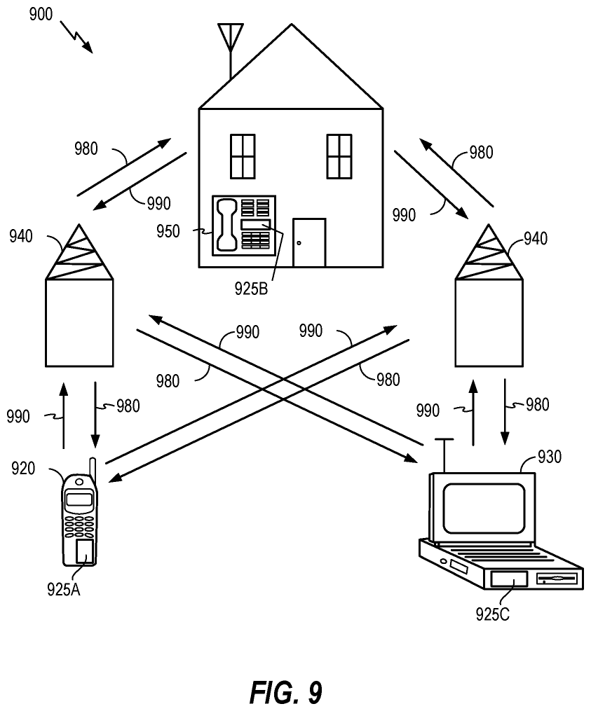

FIG. 9 is a block diagram showing an exemplary wireless communication system in which a transistor gate structure of the disclosure may be advantageously employed. For purposes of illustration, FIG. 9 shows three remote units 920, 930, and 950 and two base stations 940. It will be recognized that wireless communication systems may have many more remote units and base stations. Remote units 920, 930, and 950 include IC devices 925A, 925C, and 925B that include the disclosed transistor gate structure. It will be recognized that other devices may also include the disclosed transistor gate structure, such as the base stations, switching devices, and network equipment. FIG. 9 shows forward link signals 980 from the base station 940 to the remote units 920, 930, and 950 and reverse link signals 990 from the remote units 920, 930, and 950 to base station 940.

In FIG. 9, remote unit 920 is shown as a mobile telephone, remote unit 930 is shown as a portable computer, and remote unit 950 is shown as a fixed location remote unit in a wireless local loop system. For example, the remote units may be a mobile phone, a hand-held personal communication systems (PCS) unit, a portable data unit such as a personal data assistant, a GPS enabled devices, a navigation device, a set top box, a music player, a video player, an entertainment unit, a fixed location data unit such as meter reading equipment, or other devices that store or retrieve data or computer instructions, or combinations thereof. Although FIG. 9 illustrates remote units according to the aspects of the disclosure, the disclosure is not limited to these exemplary illustrated units. Aspects of the disclosure may be suitably employed in many devices, which include the disclosed transistor gate structure.

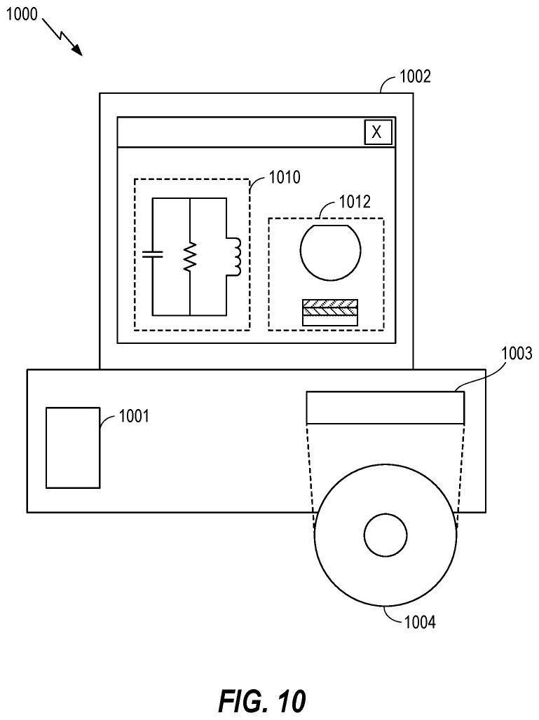

FIG. 10 is a block diagram illustrating a design workstation used for circuit, layout, and logic design of an IC structure, such as the transistor gate structure with multiple spacers. A design workstation 1000 includes a hard disk 1001 containing operating system software, support files, and design software such as Cadence or OrCAD. The design workstation 1000 also includes a display 1002 to facilitate design of a circuit 1010 or an IC device 1012 including a novel transistor gate structure. A storage medium 1004 is provided for tangibly storing the design of the circuit 1010 or the IC device 1012. The design of the circuit 1010 or the IC device 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the IC device 1012 by decreasing the number of processes for designing semiconductor wafers.

For a firmware and/or software implementation, the methodologies may be implemented with modules (e.g., procedures, functions, and so on) that perform the functions described herein. Machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A transistor gate structure comprising:
a gate having gate sidewalls, a first side and a second side opposite the first side;
an inner gate spacer on the sidewalls of the gate;
an outer gate spacer; and
a middle gate spacer between the inner gate spacer and the outer gate spacer.

2. The transistor gate structure of claim 1, in which the transistor gate structure comprises a FIN field-effect transistor, a planar field-effect transistor, a nanowire field-effect transistor or a nanosheet field-effect transistor.

3. The transistor gate structure of claim 1, in which a material of the inner gate spacer is different from a material of the middle gate spacer.

4. The transistor gate structure of claim 1, in which a material of the inner gate spacer comprises a nitride, a fluoride, a carbide or a boride.

5. The transistor gate structure of claim 1, in which a material of the middle gate spacer comprises an oxide.

6. The transistor gate structure of claim 1, in which a material of the outer gate spacer comprises a nitride.

7. The transistor gate structure of claim 1, in which the first side of the gate is on a gate oxide layer and the second side of the gate is coupled to an external device.

8. The transistor gate structure of claim 7, in which the gate oxide layer comprises a thin gate oxide layer or a thick gate oxide layer.

9. A method of fabricating a transistor gate structure comprising:
fabricating a polysilicon gate having gate sidewalls, a first side and a second side opposite the first side;
depositing a middle gate spacer on the gate sidewalls;
depositing an outer gate spacer on the middle gate spacer;
removing the polysilicon gate to create a gate cavity for a conductive gate; and
depositing an inner gate spacer on sidewalls of the middle gate spacer, the middle gate spacer between the inner gate spacer and the outer gate spacer, in which the inner gate spacer is in contact with sidewalls of the conductive gate.

10. The method of claim 9, further comprising depositing the inner gate spacer on sidewalls of the middle gate spacer after the polysilicon gate is removed and before depositing the conductive gate.

11. The method of claim 9, further comprising depositing the inner gate spacer after depositing the outer gate spacer on the middle gate spacer and before depositing the conductive gate.

12. The method of claim 9, in which fabricating the transistor gate structure comprises fabricating a FIN field-effect transistor, a planar field-effect transistor, a nanowire field-effect transistor or a nanosheet field-effect transistor.

13. The method of claim 9, in which depositing the inner gate spacer comprises depositing an inner gate spacer of a nitride material.

14. A transistor gate structure comprising:
a gate having gate sidewalls, a first side and a second side opposite the first side;
an outer gate spacer;
a middle gate spacer; and
means for strengthening the outer gate spacer and the middle gate spacer, the strengthening means on the gate sidewalls, the middle gate spacer between the strengthening means and the outer gate spacer.

15. The transistor gate structure of claim 14, in which the transistor gate structure comprises a FIN field-effect transistor, a planar field-effect transistor, a nanowire field-effect transistor or a nanosheet field-effect transistor.

16. The transistor gate structure of claim 14, in which a material of the strengthening means is different from a material of the middle gate spacer.

17. The transistor gate structure of claim 14, in which a material of the middle gate spacer comprises an oxide.

18. The transistor gate structure of claim 14, in which a material of the outer gate spacer comprises a nitride.

19. The transistor gate structure of claim 14, in which the first side of the gate is on a gate oxide layer and the second side of the gate is coupled to an external device.

20. The transistor gate structure of claim 19, in which the gate oxide layer comprises a thin gate oxide layer or a thick gate oxide layer.
